(19) United States
(12) Patent Application Publication
(10) Pub. No.: US 2007/0228555 A1
(43) Pub. Date: Oct. 4, 2007

(54) Semiconductor chip having fine pitch bumps and bumps thereon

(75) Inventors: Min O Huang, Sinshih Township (TW); Kuang Hua Liu, Sinshih Township (TW); Kuo Yu Wang, Sinshih Township (TW)

Correspondence Address: OLIFF & BERRIDGE, PLC, P.O. BOX 19928, ALEXANDRIA, VA, 22320, US

(73) Assignees: CHIPMOS TECHNOLOGIES INC., HSINCHU (TW); CHIPMOS TECHNOLOGIES (BERMUDA) LTD., HAMILTON (BM)

(21) Appl. No.: 11/529,495

(22) Filed: Sep. 29, 2006

(30) Foreign Application Priority Data
Apr. 4, 2006 (TW) 095111889

(51) Int. Cl. H01L 21/4763

(52) U.S. Cl. 257/734; 438/618

(57) ABSTRACT

A semiconductor chip has fine pitch bumps. The bumps are respectively bonded to the inner leads of a tape during a tape automatic bonding process. The surface of the semiconductor chip has a plurality of bumps. Each of the bumps has at least a first region with a larger width and a second region with a smaller width, and the heights of the first region and the second region are approximately the same. The first region allows an inner lead to be bonded together correctly when placed at a position within the tolerance. As the width of the second region is smaller, after the second region is bonded to the inner lead and is deformed, the width of the bump is preferably not larger than the width of the first region.

### BACKGROUND OF THE INVENTION

1. Field of the Invention

The present invention relates to a semiconductor chip having fine pitch bumps and bumps thereon, and more particularly relates to a semiconductor chip and bumps suitable for bonding to the inner leads of a tape in a tape automatic bonding (TAB) process.

2. Description of the Related Art

Bump technology relates to fabricating a metal cuboid, such as a gold bump, on each of the bonding pads of a semiconductor chip. A chip having bumps is applicable to various package types such as tape carrier package (TCP), chip on glass (COG), and chip on film (COF).

In the TAB (or TCP) process, the chip having bumps is aligned to a laminated tape of a copper layer and a polyimide layer first, wherein the bumps are at positions corresponding to the copper inner leads to be bonded. Then a thermal compressing head presses the chip against the tape, and bonds them together. FIG. 1 is a stereogram of a conventional TCP element 10. Copper inner leads 11 and copper outer leads 12 are disposed on a tape 13 of polyimide material. The inner leads 11 are respectively bonded with corresponding bumps 15 on a chip 14. FIG. 2 is a cross-sectional view taken along a section line A-A in FIG. 1. The inner leads 11 and the bumps 15 are bonded by means of thermal pressing, and the tape 13 supports the copper circuit between the inner leads 11 and the outer leads 12.

FIG. 3(a) is an enlarged schematic view of Part B in FIG. 1. The bump 15 which is originally cuboid expands outwardly on its two longitudinal sides after being pressed. Therefore, a gap 16 between two neighboring bumps 15 becomes narrow, and sometimes a short circuit occurs due to the deformed neighboring bumps 15. FIG. 3(b) is a top view of FIG. 3(a). This figure further illustrates the deformation of the fine pitch bumps 15. Particularly, in the subsequent encapsulation process, it is difficult for glue to flow through the narrowest portions of the gaps 16, or the phenomenon in which air is contained in vertical flows will occur at corners of the cuboids.

To sum up, the electronic package industry needs to develop a semiconductor chip equipped with bumps that prevent the defects described above from occurring, so as to improve the assembly yield of semiconductor chips having fine pitch bumps.

### SUMMARY OF THE INVENTION

One object of the present invention is to provide a semiconductor chip having fine pitch bumps and bumps thereon. Each of the bumps has at least a first region with a larger width and a second region with a smaller width. As the width of the second region is smaller, after the second region is bonded with the inner leads and is deformed, the width of the bump is preferably not larger than the width of the first region, i.e., the material for encapsulation flows more easily through the gap between two deformed bumps, and the occurrence of voids is prevented.

Another object of the present invention is to provide a bump with an improved shape, which assists the encapsulation material in totally covering the surface of the chip, and reduces the resistance to flow.

Moreover, still another object of the present invention is to provide a bump with an improved shape, which is mainly used to reduce the possibility of short circuits between bumps and between inner leads.

To achieve the aforementioned objects, the present invention discloses a semiconductor chip having fine pitch bumps and bumps thereof. The bumps are respectively bonded to the inner leads of a tape during a tape automatic bonding process. The surface of the semiconductor chip has a plurality of bumps. Each of the bumps has at least a first region with a larger width and a second region with a smaller width, and the heights of the first region and the second region are approximately the same. The first region allows an inner lead to be bonded together correctly when placed at a position within the tolerance. As the width of the second region is smaller, after the second region is bonded to the inner lead and is deformed, the width of the bump is preferably not larger than the width of the first region.

The bump is I-shaped, wherein two ends of the bump are cuboid first regions with a larger width. The part connecting the two first regions is a second region with a smaller width, and the second region is also a cuboid as well.

The bump has a cylindrical shape, wherein the band-shaped part centering on the diameter is a first region with a larger width, and the parts disposed on two sides of the first region are chord-shaped second regions with a smaller width.

### BRIEF DESCRIPTION OF THE DRAWINGS

The invention will be described according to the appended drawings in which:

FIG. 1 is a stereogram of a conventional tape carrier package device;

FIG. 2 is a cross-sectional view taken along a section line A-A in FIG. 1;

FIG. 3(a) is an enlarged schematic view of Part B in FIG. 1;

FIG. 3(b) is a top view of FIG. 3(a);

FIG. 4 is a partial stereogram of a semiconductor chip having fine pitch bumps in accordance with the present invention;

FIG. 5 is a schematic view of the fine pitch bumps and inner leads after being bonded in accordance with the present invention;

FIG. 6 is a top view of fine pitch bumps in accordance with the second embodiment of the present invention;

FIG. 7 is a top view of fine pitch bumps in accordance with the third embodiment of the present invention; and

FIG. 8 is a top view of fine pitch bumps of the fourth embodiment of the present invention.

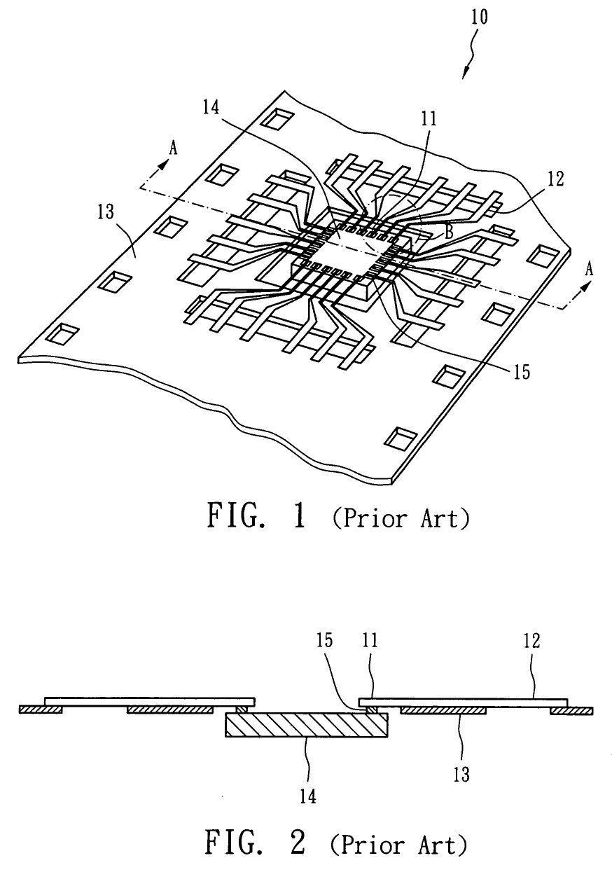

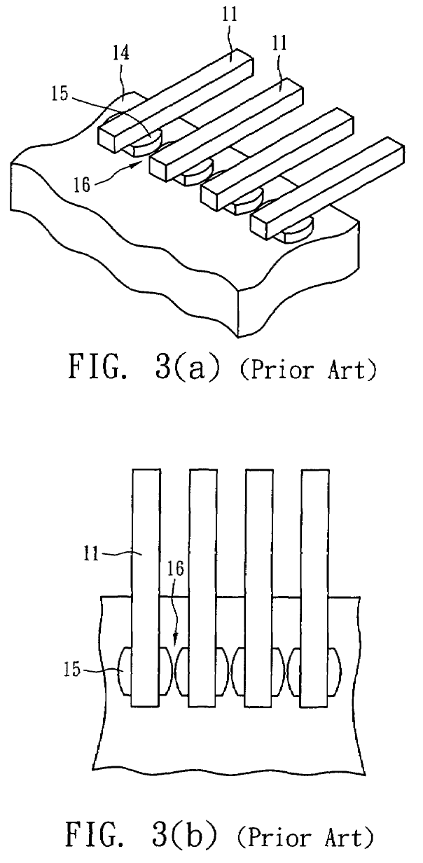

### DETAILED DESCRIPTION OF THE INVENTION

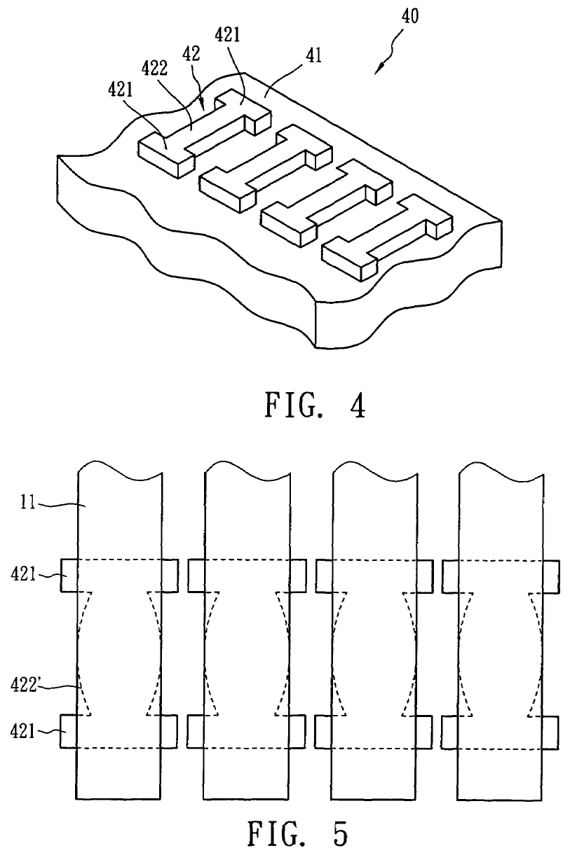

FIG. 4 is a partial stereogram of a semiconductor chip having fine pitch bumps of the present invention. A semiconductor chip 40 is a substrate 41 on which an integrated circuit is formed, and has a plurality of bumps 42. Each of the bumps 42 is I-shaped, wherein the two ends of a bump 42 are cuboid first regions 421 with a larger width (cuboid is shown in the figure, but other shapes are also suitable for the bumps 42), the part connecting the two first regions 421 is a second region 422 with a smaller width, and the second region 422 is also a cuboid as well. The heights of the first regions 421 and the second region 422 are approximately the same. The first regions 421 allow inner leads to be bonded correctly when placed at a position within the tolerance, that is, when the inner leads align the bumps 42 in the tolerance, even if the alignment is oblique, the short circuit will not occur.

FIG. 5 is a schematic view of fine pitch bumps and the inner leads 11 of the present invention after being bonded. Obviously, the deformation of the second region 422′ after being pressed by the inner lead 11 is preferably not larger than the width of the first regions 421. Thus, the encapsulation material can flow through the gap between two deformed bumps 42, thereby preventing the generation of voids during the encapsulation, and avoiding short circuits between bumps.

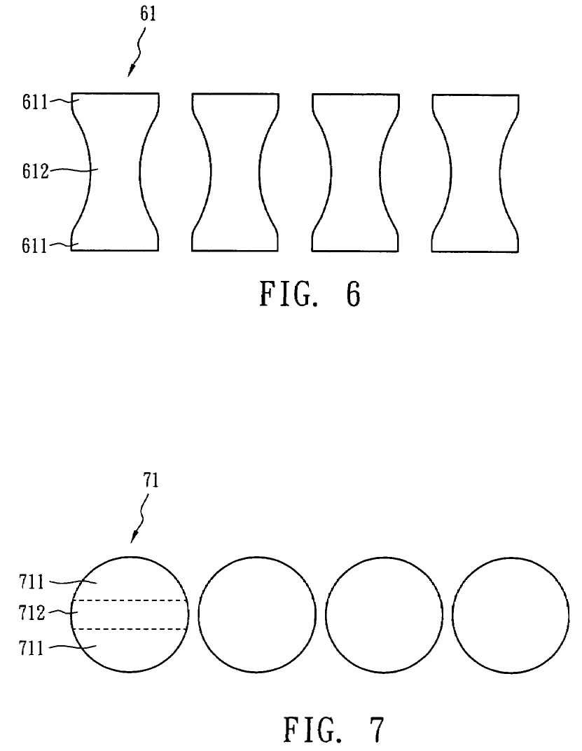

In addition to the I-shaped bumps 42 that achieve the objects of the present invention, FIG. 6 shows a top view of fine pitch pumps 61 in accordance with another embodiment of the present invention. Each of the bumps 61 has a streamlined shape like an hourglass, wherein the two ends of a bump 61 are two first regions 611 with a larger width and the part connecting the two the first regions 611 is a second region 612 with a smaller width. The shape of the second region 612 is similar to a biconcave lens. The first region 611 allows inner leads to be bonded correctly when placed at a position within the tolerance, that is, when the inner leads align the bumps 61 in the tolerance, the inner lead bonding will not become oblique, and the short circuits between the inner leads and between the bumps will not occur.

The bump 61 with a streamlined profile can slightly reduce the resistance to the flow of the encapsulation material, and prevent the phenomenon of turbulence. Therefore, this concept can be extended to bumps 71 having a cylindrical shape in FIG. 7. The band-shaped part centering on the diameter in the middle of each of the bumps 71 is a first region 712 with a larger width, and the parts disposed on two sides of the first region are chord-shaped second regions 711 with a smaller width. Even if the first region 712 with a larger width is deformed after being pressed, the narrowed channel between two adjacent deformed first regions 712 still only occupies a small part of the gap between two bumps 71. By contrast, the long narrowed channel between the deformed conventional cuboid bumps seriously impacts the flow of fluids. However, the chord-shaped second regions 711 on two sides are greatly helpful to the inflow and outflow of fluids, and effectively prevent the phenomenon in which air is contained in eddy flows.

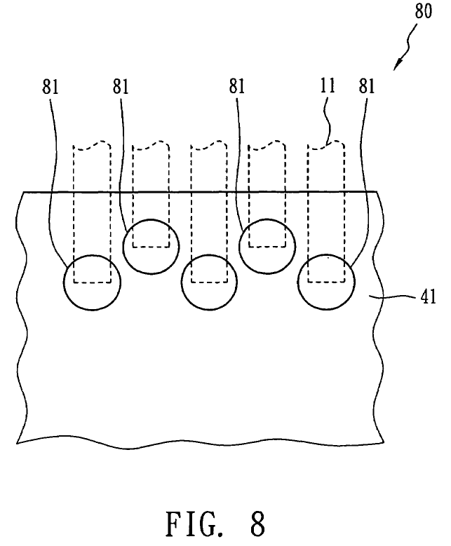

In addition to arranging the cylindrical bumps 71 in an approximately straight line, bumps 82 on a semiconductor chip 80 can be arranged in a staggered mode, as shown in FIG. 8. Thus, the distance of the gap between the two neighboring bumps 82 is increased, and is even larger than the width of the smallest gap in FIG. 7. In other words, it is easier for the encapsulation material to pass through, and the occurrence of voids containing air is prevented effectively. In this embodiment, such staggered arrangement can also increase the capacity of the bumps for the same semiconductor chip.

The above-described embodiments of the present invention are intended to be illustrative only. Numerous alternative embodiments may be devised by persons skilled in the art without departing from the scope of the following claims.

What is claimed is:

1. A semiconductor chip having fine pitch bumps applicable for inner lead bonding in a tape automatic bonding process, comprising:
a substrate with an integrated circuit formed; and
a plurality of bumps disposed on the substrate, including:
at least a first region; and
at least a second region, wherein the width of the second region is smaller than the width of the first region.

2. The semiconductor chip having fine pitch bumps of claim 1, wherein the first region is aligned with an inner lead while the inner lead is bonded to the bump, and which allows the inner lead to be correctly bonded when the inner lead is placed at a position with a tolerance.

3. The semiconductor chip having fine pitch bumps of claim 1, wherein the width of the second region is smaller, and the width of the deformed second region after being bonded with the inner lead is preferably not larger than the width of the first region.

4. The semiconductor chip having fine pitch bumps of claim 1, wherein the bump has the two first regions disposed on the two ends of the bump respectively and the one second region connects the two first regions.

5. The semiconductor chip having fine pitch bumps of claim 4, wherein the bump is I-shaped.

6. The semiconductor chip having fine pitch bumps of claim 4, wherein the bump is hourglass-shaped.

7. The semiconductor chip having fine pitch bumps of claim 1, wherein the bump has the two second regions disposed on the two ends of the bump respectively and the one first region connects the two second regions.

8. The semiconductor chip having fine pitch bumps of claim 7, wherein the bump has a cylindrical shape.

9. The semiconductor chip having fine pitch bumps of claim 1, wherein the bumps are arranged on the substrate in a staggered manner.

10. The semiconductor chip having fine pitch bumps of claim 1, wherein the bumps are arranged in at least two straight lines, and the bumps arranged in the two straight lines appear in a staggered manner.

11. A bump, comprising:
at least a first region; and
at least a second region, wherein the width of the second region is smaller than that of the first region.

12. The bump of claim 11, wherein heights of the first region and the second region are approximately the same.

13. The bump of claim 11, wherein the bump has the two first regions disposed on the two ends of the bump respectively and the one second region connects the two first regions.

14. The bump of claim 13, wherein the bump is I-shaped.

15. The bump of claim 13, wherein the bump is hourglass-shaped.

16. The bump of claim 11, wherein the bump has the two second regions disposed on the two ends of the bump respectively and the one first region connects the two second regions.

17. The bump of claim 16, wherein the bump has a cylindrical shape.
